(19) United States
(12) Patent Application Publication
(10) Pub. No.: US 2023/0280653 A1
(43) Pub. Date: Sep. 7, 2023

(54) SURFACE TREATMENT TO PHOTOSENSITIVE LAYER

(71) Applicant: TAIWAN SEMICONDUCTOR MANUFACTURING COMPANY, LTD., Hsinchu (TW)

(72) Inventors: Wei-Han LAI, New Taipei City (TW); Ching-Yu CHANG, Yilang County (TW)

(73) Assignee: TAIWAN SEMICONDUCTOR MANUFACTURING COMPANY, LTD., Hsinchu (TW)

(21) Appl. No.: 17/679,463

(22) Filed: Feb. 24, 2022

(51) Int. Cl. G03F 7/09; G03F 7/38; G03F 7/004

(52) U.S. Cl. CPC G03F 7/092; G03F 7/0045; G03F 7/094; G03F 7/38; H01L 21/0332

(57) ABSTRACT

A method includes forming a tri-layer structure over a substrate, in which the tri-layer structure includes a bottom layer, a middle layer over the bottom layer and a photosensitive layer, patterning the photosensitive layer, performing a surface treatment on the patterned photosensitive layer to form a protection layer at least on a sidewall of the patterned photosensitive layer, patterning the middle layer after performing the surface treatment, patterning the bottom layer, and etching the substrate.

### BACKGROUND

As modern integrated circuits shrink in size, the associated features shrink in size as well. Lithography is a mechanism by which a pattern on a mask is projected onto a substrate such as a semiconductor wafer. In areas such as semiconductor photolithography, it has become necessary to create images on the semiconductor wafer which incorporate minimum feature sizes under a resolution limit or critical dimension (CD). Semiconductor photolithography typically includes the steps of applying a coating of photoresist (also referred to as resist) on a top surface (e.g., a thin film stack) of a semiconductor wafer and exposing the photoresist to a pattern. The semiconductor wafer is then transferred to a developing chamber to remove the exposed resist, which is soluble to an aqueous developer solution. As a result, a patterned layer of photoresist exists on the top surface of the wafer.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1 and 2 illustrate a flowchart of an exemplary method according to various aspects of the present disclosure.

FIGS. 3-10 are fragmentary cross-sectional views of an exemplary workpiece at intermediate steps of an exemplary method according to various aspects of the present disclosure.

FIGS. 11, 12 and 13A illustrate perspective views of additional fabrication processes in the formation of a semiconductor device using a workpiece in accordance with some embodiments of the present disclosure.

FIGS. 13B, 14, 15 and 16 illustrate cross-sectional views of additional fabrication processes in the formation of an integrated circuit structure using a substrate in accordance with some embodiments of the present disclosure.

FIGS. 17-21 are fragmentary cross-sectional views of an exemplary workpiece at intermediate steps of an exemplary method according to various aspects of the present disclosure.

FIG. 22 illustrates exemplary chemical formulas of repeating units of portions of a protection layer in accordance with some embodiments of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within +/-10% of the number described, unless otherwise specified. For example, the term “about 5 nm” encompasses the dimension range from 4.5 nm to 5.5 nm.

The present disclosure relates generally to an integrated circuit (IC) device manufacturing and, more particularly, to device patterning processes using a multi-layer (e.g., a tri-layer) structure. The tri-layer structure may include a photoresist layer, a middle layer (e.g., a hard mask layer), and a bottom layer (e.g., bottom anti-reflective coating (BARC)) formed on a substrate has demonstrated advantages in minimizing substrate reflectivity of a light (e.g., radiation) source and increasing etching selectivity between the bottom layer and the middle layer. However, improvements in the tri-layer structure for advanced patterning processes are still desired. For example, it has been observed that patterning the tri-layer structure (e.g., photoresist layer, middle layer and bottom layer) may cause lateral etching (in the horizontal direction) that may cause unwanted sidewall profiles in the middle layer and the bottom layer (e.g., oval profile or undercut profile), leading to overlay alignment inaccuracy and critical dimension (CD) variation. As demonstrated by embodiments below, performing a surface treatment to the photoresist layer prior to etching the middle layer or performing a surface treatment to the photoresist layer and the middle layer prior to etching the bottom layer can remedy these and other adverse effects, thus improving the quality of the middle layer and the bottom layer during the lithography patterning process.

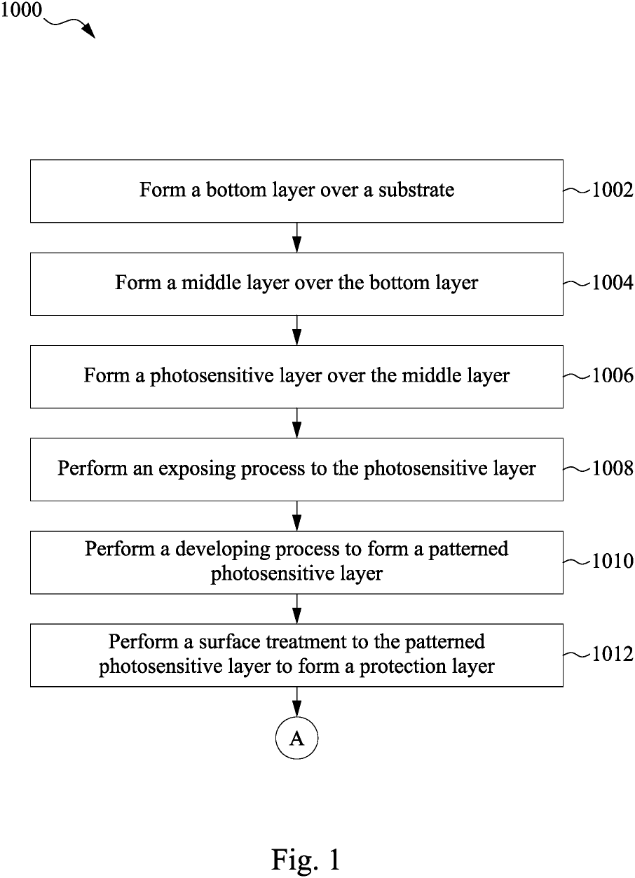

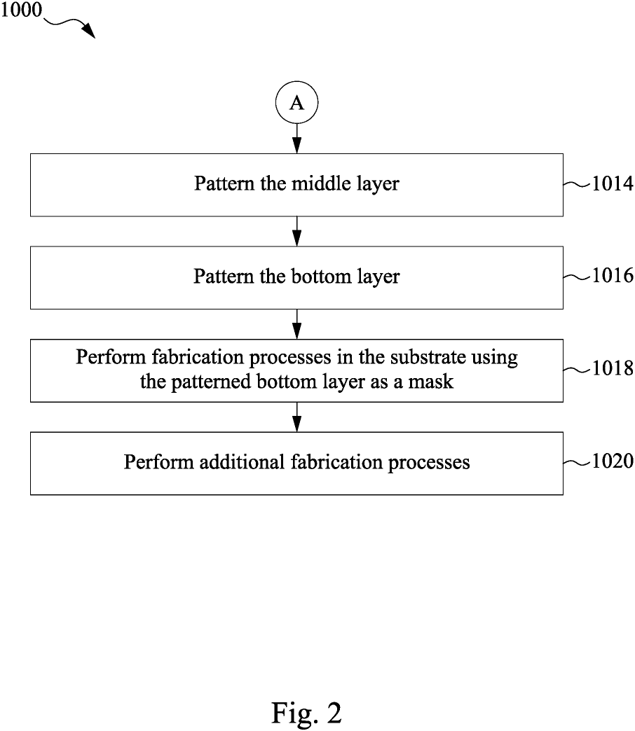

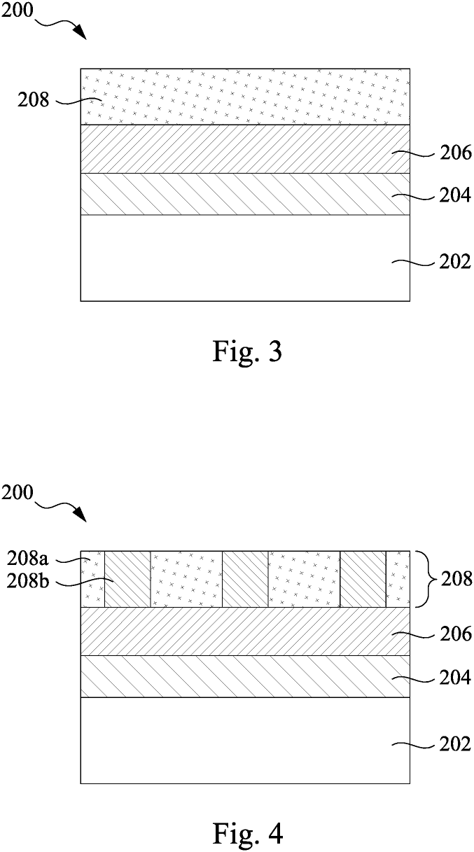

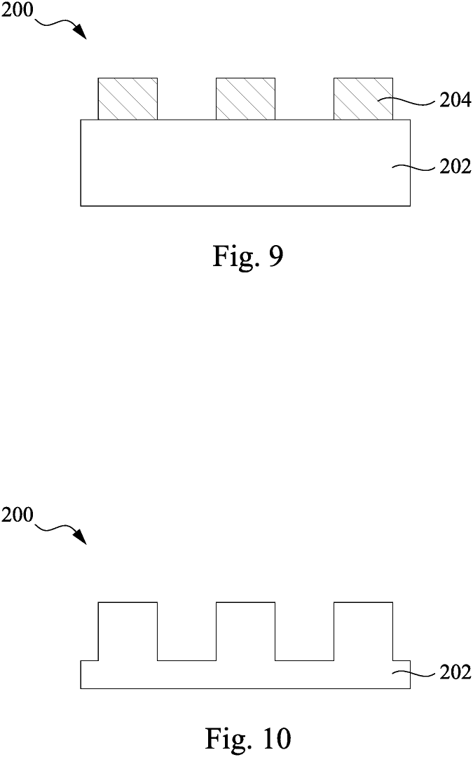

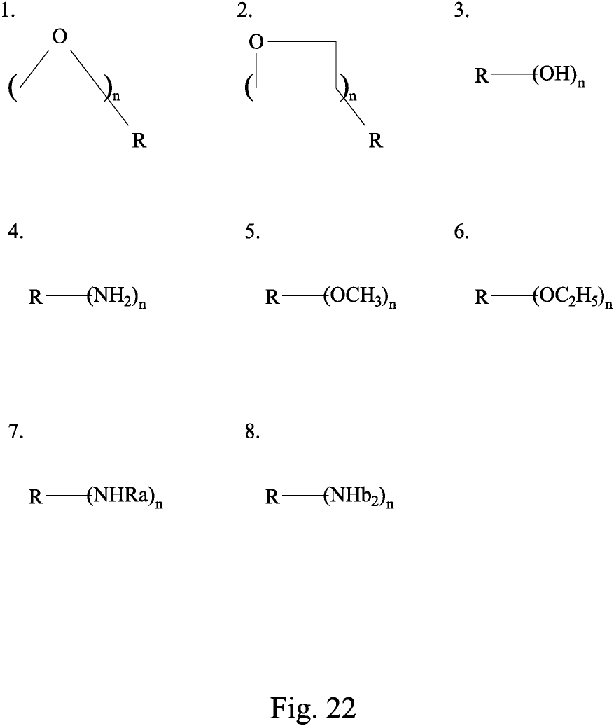

FIGS. 1 and 2 illustrate a flowchart of a method 1000 for patterning a workpiece 200 (see FIG. 3) according to some aspects of the present disclosure. The method 1000 is merely an example, and is not intended to limit the present disclosure beyond what is explicitly recited in the claims. Additional operations can be provided before, during, and after the method 1000, and some operations described can be replaced, eliminated, or moved around for additional embodiments of the process. Intermediate steps of the method 1000 are described with reference to cross-sectional views of the workpiece 200 as shown in FIGS. 3-10, while schematic representations of exemplary chemical structures of a protection layer shown in FIG. 22. For clarity and ease of explanation, some elements of the figures have been simplified.

Referring to block 1002 of FIG. 1 and to FIG. 3, a bottom layer 204 is formed on a substrate 202 for patterning of the workpiece 200. The substrate 202 may include an elementary (single element) semiconductor, such as silicon and/or germanium; a compound semiconductor, such as silicon carbide, gallium arsenic, gallium phosphide, indium phosphide, indium arsenide, and/or indium antimonide; an alloy semiconductor such as SiGe, GaAsP, AllnAs, AlGaAs, GaInAs, GaInP, and/or GaInAsP; a non-semiconductor material, such as soda-lime glass, fused silica, fused quartz, and/or calcium fluoride (CaF2); and/or combinations thereof.

The substrate 202 may be a single-layer material having a uniform composition; alternatively, the substrate 202 may include multiple material layers having similar or different compositions suitable for IC device manufacturing. In one example, the substrate 202 may be a silicon-on-insulator (SOI) substrate having a semiconductor silicon layer formed on a silicon oxide layer. In other example, the substrate 202 may include a conductive layer, a semiconductor layer, a dielectric layer, other layers, and/or combinations thereof.

The substrate 202 may include various circuit features formed thereon including, for example, field effect transistors (FETs), metal-oxide semiconductor field effect transistors (MOSFETs), complementary metal-oxide semiconductor (CMOS) transistors, high voltage transistors, high frequency transistors, bipolar junction transistors, diodes, resistors, capacitors, inductors, varactors, other suitable devices, and/or combinations thereof.

In some embodiments where the substrate 202 includes FETs, various doped regions, such as source/drain regions, are formed on the substrate 202. The doped regions may be doped with p-type dopants, such as phosphorus or arsenic, and/or n-type dopants, such as boron or BF₂, depending on design requirements. The doped regions may be planar or non-planar (e.g., in a fin-like FET device) and may be formed directly on the substrate 202, in a P-well structure, in an N-well structure, in a dual-well structure, or using a raised structure. Doped regions may be formed by implantation of dopant atoms, in-situ doped epitaxial growth, and/or other suitable techniques.

In many embodiments, the bottom layer 204 is a bottom anti-reflective coating (BARC) whose composition is chosen to minimize reflectivity of the light source implemented during exposure of a subsequently-formed photoresist layer (e.g., photosensitive layer 208) formed over the bottom layer 204. The bottom layer 204 may be formed by suitable process including atomic layer deposition (ALD) or chemical vapor deposition (CVD) onto a top surface of the substrate (or a top surface of a topmost layer of a multi-layer substrate 202), and may be formed to any suitable thickness. In some embodiments where the bottom layer 204 formed by ALD, the bottom layer 204 includes titanium nitride (TiN), titanium dioxide (TiO₂), titanium oxynitride (TiON), silicon dioxide (SiO₂), aluminum oxide (Al₂O₃), tungsten (W), tungsten oxide (WO₂), tungsten nitride (WN), hafnium oxide (HfO₂), and/or other suitable material. In some embodiments where the bottom layer 204 is formed by CVD, the bottom layer 204 includes polysilicon, silicon dioxide (SiO₂), silicon nitride (SiN), amorphous silicon, amorphous carbon, and/or other suitable material.

Referring to block 1004 of FIG. 1 and still to FIG. 3, a middle layer 206 is formed over the bottom layer 204. The middle layer 206 may be formed by suitable process including spin-on coating, atomic layer deposition or chemical vapor deposition, and may be formed to any suitable thickness. The middle layer 206 may be a single-layer structure or may include a number of layers, each of which may include a dielectric, a metal, a metal compound, and/or other suitable material. In many embodiments, the middle layer 206 includes spin-on-glass (SOG) or spin-on-carbon (SOC). In some embodiments where the middle layer 206 is formed by ALD, the middle layer 206 includes titanium nitride (TiN), titanium dioxide (TiO₂), titanium oxynitride (TiON), silicon dioxide (SiO₂), silicon nitride (SiN), aluminum oxide (Al₂O₃), tungsten (W), hafnium oxide (HfO₂), and/or other suitable material. In some embodiments where the middle layer 206 is formed by CVD, the middle layer 206 includes polysilicon, silicon dioxide (SiO₂), silicon nitride (SiN), amorphous silicon, amorphous carbon, and/or other suitable material. The composition of the middle layer 206 is chosen such that the middle layer 206 can be selectively etched without substantially etching the bottom layer 204. In other words, the middle layer 206 and the bottom layer 204 include materials having distinct etching sensitivities towards a given etchant.

Referring to block 1008 of FIG. 1 and still to FIG. 3, a photosensitive layer (e.g., a coating or a film) 208 is formed over the middle layer 206. The photosensitive layer 208 is formed by spin-on coating process. In some embodiments, the photosensitive layer 208 is further treated with a soft baking process. In particular, the photosensitive layer 208 may include any lithographically sensitive resist material. In some embodiments, the photosensitive layer 208 is sensitive to a radiation, such as I-line light, a deep ultraviolet (DUV) light (e.g., 248 nm radiation by krypton fluoride (KrF) excimer laser or 193 nm radiation by argon fluoride (ArF) excimer laser), an extreme ultraviolet (EUV) light (e.g., 135 nm light), an electron beam (e-beam), and an ion beam. For example, the photosensitive layer 208 includes a photoresist, spin-on carbon (SOC), or a silicon-containing organic polymer, for example, the material may include spin-on glass (SOG).

The photosensitive layer 208 may include a photosensitive chemical, a polymeric material and a solvent. The photosensitive layer 208 may be a positive-tone or negative-tone resist material and may have a multi-layer structure. Furthermore, the photosensitive layer 208 may be implemented with a chemical amplification (CA) resist material. In one embodiment, a positive-tone CA resist material includes a polymeric material (not depicted) that becomes soluble in a developer after the polymer is exposed to acidic moieties. Alternatively, a negative-tone CA resist material includes a polymeric material (not depicted) that becomes insoluble in a developer after the polymer is exposed acidic moieties.

In many embodiments, the photosensitive layer 208 includes a polymer having a backbone (not shown) with a plurality of functional groups (not shown) attached thereto. The polymer backbone may be an acrylate-based polymer or a poly(norbornene)-co-malaic anhydride (COMA) polymer, while the functional groups may include moieties that assist any subsequent exposure and developing processes. In one example, the functional groups may include lithographically sensitive groups (e.g., sensitizers) such as phenol, styrene, fluoride, and/or other suitable groups.

In many embodiments, the photosensitive layer 208 includes one or more photo-acid generators (PAGs) that produce acidic moieties in response to radiation exposure. In many embodiments, the PAGs found in the photosensitive layer 208 are sensitive to radiation. The photosensitive layer 208 may also include a photo-decomposable base (PDB) that, as the name suggests, decomposes basic moieties in response to the radiation source. In some embodiments, the PDBs have different photo-sensitivity compared to the PAGs.

The photosensitive layer 208 may further include a photo-decomposable quencher (PDQ) to reduce concentration of acidic moieties in regions where chemical changes (e.g., changes in solubility) are not desired. For a positive-tone resist material, for example, these regions may include unexposed or marginally-exposed regions of the photosensitive layer 208 that border exposed regions. The photosensitive layer 208 may also include a number of additives such as crosslinking agents (e.g., tetramethylolglycoluril (TMGU) linker, or epoxy linker), surfactant, chromophores, and/or solvents.

The photosensitive layer 208 may be applied by any suitable technique, and in an exemplary embodiment, the photosensitive layer 208 is applied in a liquid form using a spin-on (i.e., spin coating) technique. A spin coating process may use centrifugal force to disperse the material layer in a liquid form across a surface of an underlying substrate (e.g., the middle layer 206) in a uniform thickness. To facilitate application, the material layer may include a solvent, which when removed, leaves the material layer in a solid or semisolid form (e.g., a film). The solvent may be one or more of the following: propylene glycol methyl ether acetate, propylene glycol monomethyl ether, gamma-butyrolactone, ethyl lactate, cyclohexanone, n-butyl actetate, ethyl ketone, dimethyl formamide, alcohol (e.g., isopropyl alcohol or ethanol), or other suitable solvent. The solvent may be driven off as part of the spin coating, during a settling process, and/or during a post-application/pre-exposure baking process. The pre-exposure baking process may be implemented by any suitable equipment such as, for example, a hotplate, at any temperature suitable for the particular compositions of the photosensitive layer 208 and the solvent employed.

Referring to block 1008 of FIG. 1 and to FIG. 4, an exposing process is performed to the photosensitive layer 208 to form a latent pattern on the photosensitive layer 208. The latent pattern refers to the exposed pattern on the photosensitive layer 208, which eventually becomes a physical pattern, such as by a developing process. The latent pattern of the photosensitive layer 208 includes unexposed portions 208a and exposed portions 208b. In the present case, of the latent pattern, the exposed portions 208b of the photosensitive layer 208 are physically or chemically changed. In some examples, the exposed portions 208b are de-protected, inducing polarity change for dual-tone imaging (developing). In other examples, the exposed portions 208b are changed in polymerization, such as depolymerized as in positive resist or cross-linked as in negative resist.

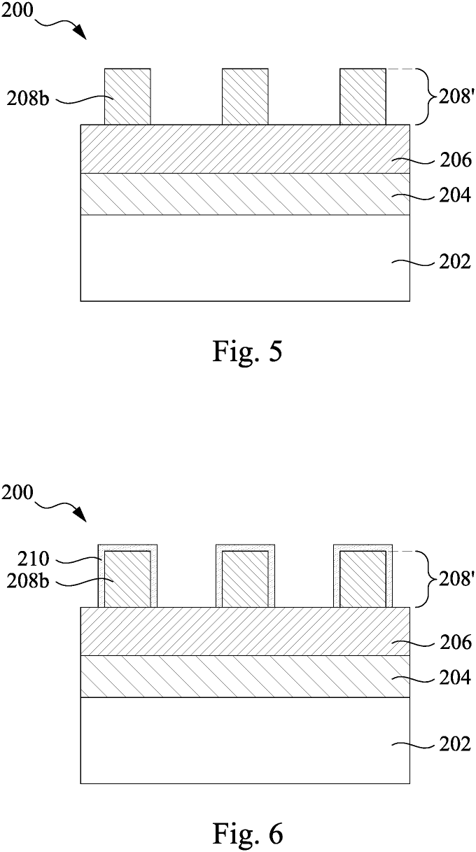

Referring to block 1010 of FIG. 1 and to FIG. 5, a developing process is performed to develop the photosensitive layer 208 in a developer, constructed in accordance with some embodiments. By the developing process, a patterned photosensitive layer 208′ is formed. In some embodiments, the photosensitive layer 208 experiences a polarity change after the block 1010, and a dual-tone developing process may be implemented. In some examples, the photosensitive layer 208 is changed from a nonpolar state (hydrophobic state) to a polar state (hydrophilic state), then the exposed portions 208b will be removed by an aqueous solvent (positive tone imaging), such as tetramethyl ammonium hydroxide (TMAH), or alternatively the unexposed portions 208a will be removed by an organic solvent (negative tone imaging), such as butyl acetate. In some other examples, the photosensitive layer 208 is changed from a polar state to a nonpolar state, then the exposed portions 208b will be removed by an organic solvent (positive tone imaging) or the unexposed portions 208a will be removed by an aqueous solvent (negative tone imaging).

In the present example illustrated in FIG. 5, the unexposed portions 208a are removed in the developing process. In this example shown in FIG. 5, the patterned photosensitive layer 208′ is represented by three line patterns. However, the following discussion is equally applicable to resist patterns represented by trenches.

Referring to block 1012 of FIG. 1 and to FIG. 6, a surface treatment is performed to the patterned photosensitive layer 208′ to form a protection layer 210 on the patterned photosensitive layer 208′ in accordance with some embodiments. The protection layer 210 surrounds the patterned photosensitive layer 208′. As described in greater detail below, the protection layer 210 is configured to protect the patterned photosensitive layer 208′ during a subsequent etching process.

To protect the patterned photosensitive layer 208′, the protection layer 210 includes a cross-linkable composition to cross-link with an exposed surface of patterned photosensitive layer 208′. For example, the cross-linkable composition has a reactive functional group configured to cross-link or interact with the exposed surface of the patterned photosensitive layer 208′. In greater detail, the protection layer 210 reacts with a top surface and sidewalls of the patterned photosensitive layer 208′ in a cross-link reaction while not reacting with or not cross-linking an exposed surface of the middle layer 206. For example, the cross-linkable composition of the protection layer 210 may include one or more of repeating units 1-8 of FIG. 22. In FIG. 22, the repeating units 1-2 include epoxy groups. The repeating unit 3 includes hydroxyl group. The repeating unit 4 includes amine group. The repeating unit 5 includes methoxy group. The repeating unit 6 includes ethoxy group. The repeating unit 7 includes NHRa group. The repeating unit 8 includes N(Rb)₂ group. In FIG. 22, R is alkyl group, cycloalkyl group, hydroxylalkyl group, alkoxy group, alkoxyl alkyl group, acetyl group, acetyl alkyl group, aromatic group, halogen alkyl, or halogen alkyl containing aromatic derivatives and R has a molecular weight in a range from about 50 to about 15000. In FIG. 22, Ra and Rb are each independently C1-C6 alkyl group, cycloalkyl group, hydroxylalkyl group, alkoxy group, alkoxyl alkyl group, acetyl group, or acetyl alkyl group, and n is in a range from 1 to 200. In some embodiments, the surface treatment to form the protection layer 210 can be performed by preparing the cross-linkable composition in an appropriate solvent or without solvent. The solvent can be any suitable solvent for dissolving the cross-linkable composition. For example, the solvent may be an organic solvent or water. An amount of the cross-linkable composition in the protection layer 210 is from 0.01 to 100 percent by weight.

Hydrophilicity may be expressed in terms of “log P”. Log P is the logarithm of the partition coefficient, P, where P is a ratio of concentrations of an un-ionized compound in the two phases of a mixture of two immiscible solvents at equilibrium, one solvent being water and the second a hydrophobic solvent, most commonly octanol. Hence log P is a measure of differential solubility of the substance between the water and the hydrophobic solvent, i.e., a measure of hydrophilicity or hydrophobicity. Hydrophobic compounds will have a high log P and hydrophilic compounds a low or negative log P. In case of the protection layer 210 being formed by the cross-linkable composition and the organic solvent, the partition ratio log P value of the organic solvent is lower than 4.

In some embodiments, the surface treatment to form the protection layer 210 is carried out by dispensing, vapor deposition, soaking the workpiece 200 into a bath, or other suitable methods.

In some embodiments, an unreacted portion of the protection layer 210 can be removed by performing a rinsing process using water (e.g., de-ionized water) or organic solvent as a rinsing agent. In some embodiments, a baking process may be further performed to the protection layer 210 before or after removing the unreacted portion of the protection layer 210. The baking process is configured to help the protection layer 210 to be fixed onto the top surface and the sidewalls of the patterned photosensitive layer 208′.

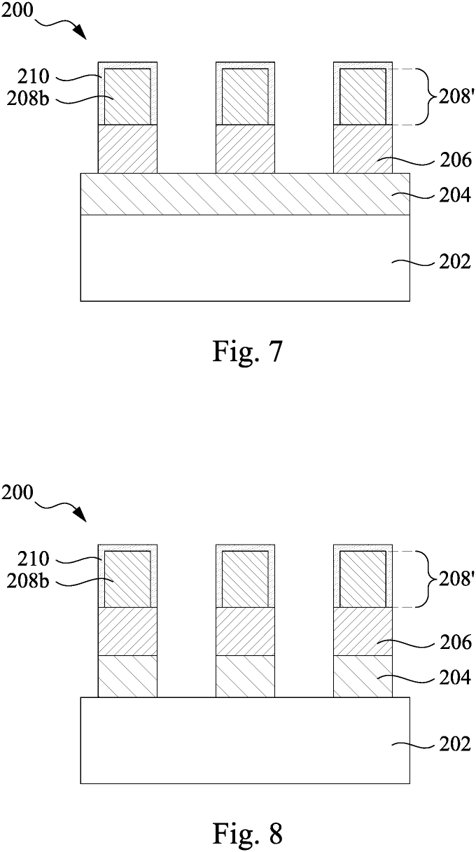

Referring to block 1014 of FIG. 2 and to FIG. 7, the middle layer 206 is patterned by an etching process. For example, portions of the middle layer 206 are selectively removed in an etching process using the patterned photosensitive layer 208′protected by the protection layer 210 as an etch mask. The process of etching the middle layer 206 can be chosen such that the middle layer 206 has an etch rate higher than an etch rate of the protection layer 210. In some embodiments, although the patterned photosensitive layer 208′ may have a low etch resistance to the etching process of etching the middle layer 206, the protection layer 210 has a higher etch resistance to the etching process of etching the middle layer 206 than that of the patterned photosensitive layer 208′. Therefore, the etching conditions (e.g., etchant chemicals, temperature, pressure, bias of dry etching, pH value of wet etching, and so on) for etching the middle layer 206 can be selected to form an improved sidewall profile for the middle layer 206, with more relaxed concern about damages to the photosensitive layer 208. In this way, the resultant middle layer 206 can have a substantially vertical sidewall profile without significantly damaging the overlying layer (e.g., the patterned photosensitive layer 208′ and the protection layer 210). As a result, the overlay alignment inaccuracy and critical dimension (CD) variation can be prevented. The etching process at block 1014 demonstrates etching selectivity for the middle layer 206 over the underlying bottom layer 204.

In some embodiments, the middle layer 206 is etched using any suitable method including a dry etching process, a wet etching process, other suitable etching process, a reactive ion etching (RIE) process, or combinations thereof. In an exemplary embodiment, a dry etching process is implemented and employs an etchant gas that includes oxygen, nitrogen, hydrogen, a fluorine-containing etchant gas (e.g., CₓF_{y}), other suitable gases and/or plasmas, or combinations thereof. In an exemplary embodiment, a wet etching process is implemented and employs an etchant solution with a pH value of greater than 8 or lower than 5. In some embodiments, the etchant solution includes HF solution.

Referring to block 1016 of FIG. 2 and to FIG. 8, the bottom layer 204 is patterned by an etching process. For example, portions of the bottom layer 204 (i.e., the BARC layer) are selectively removed using the middle layer 206 and the patterned photosensitive layer 208′ protected by the protection layer 210 together as an etch mask. The protection layer 210 is configured to protect the patterned photosensitive layer 208′ during etching the bottom layer 204. The process of etching the bottom layer 204 is chosen such that the bottom layer 204 has an etch rate higher than an etch rate of the protection layer 210 and the middle layer 206. In some embodiments, although the patterned photosensitive layer 208′ may have a low etch resistance to the etching process of etching the bottom layer 204, the protection layer 210 has a higher etch resistance to the etching process of etching the bottom layer 204 than that of the patterned photosensitive layer 208′. Therefore, an etchant for etching the bottom layer 204 can create the sidewalls of a remaining portion of the bottom layer 204 that are substantially vertical while not etching the overlay layer (e.g., the patterned photosensitive layer 208′ and the protection layer 210). Therefore, the remaining portion of the bottom layer 204 is drawn with vertical lines. As a result, the overlay alignment inaccuracy and critical dimension (CD) variation can be prevented. The bottom layer 204 has a material with an etch selectivity to the material of the underlying substrate 202.

In some embodiments, the bottom layer 204 is etched using any suitable method including a dry etching process, a wet etching process, other suitable etching process, a reactive ion etching (RIE) process, or combinations thereof. In an exemplary embodiment, a dry etching process is implemented and employs an etchant gas that includes oxygen, nitrogen, hydrogen, a fluorine-containing etchant gas (e.g., CₓF_{y}), other suitable gases and/or plasmas, or combinations thereof. In an exemplary embodiment, a wet etching process is implemented and employs an etchant solution with a pH value of greater than 8 or lower than 5. In some embodiments, the etchant solution includes HF solution.

The patterned photosensitive layer 208′ and the protection layer 210 are subsequently removed from the workpiece 200 by an ashing operation or any suitable method. Afterwards, the middle layer 206 is removed by a dry etching process, a wet etching process, or other suitable etching process.

Referring to block 1018 of FIG. 2 and to FIG. 10, fabrication processes are performed in the substrate 202 using the patterned bottom layer 204 as a mask. Any suitable method may be performed to process the substrate 202 including a deposition process, an implantation process, an epitaxial growth process, and/or any other fabrication process. In an exemplary embodiment, the substrate 202 is etched using the patterned bottom layer 204 as an etch mask. In some embodiments, the substrate 202 is etched using any suitable method including a dry etching process, a wet etching process, other suitable etching process, an RIE process, or combinations thereof. As discussed previously, with reference to FIGS. 7 and 8, by using the patterned photosensitive layer 208′ protected by the protection layer 210, the overlay alignment inaccuracy and critical dimension (CD) variation can be prevented. Therefore, the pattern dimension accuracy of the substrate 202 can be improved. However, it is understood that the concepts of the present disclosure apply to any fabrication process performed on the substrate 202. In various examples, the processed substrate 202 is used to fabricate a gate stack, to fabricate an interconnect structure, to form non-planar devices by etching to expose a fin or by epitaxially growing fin material, and/or other suitable applications. The bottom layer 204 is subsequently removed using any suitable method after the substrate 202 is processed.

Referring to block 1020 of FIG. 2, the workpiece 200 may then be provided for additional fabrication processes. For example, the workpiece 200 may be used to fabricate an integrated circuit chip, a system-on-a-chip (SOC), and/or a portion thereof, and thus the subsequent fabrication processes may form various passive and active microelectronic devices such as resistors, capacitors, inductors, diodes, metal-oxide semiconductor field effect transistors (MOSFET), CMOS transistors, bipolar junction transistors (BJT), laterally diffused MOS (LDMOS) transistors, high power MOS transistors, other types of transistors, and/or other circuit elements.

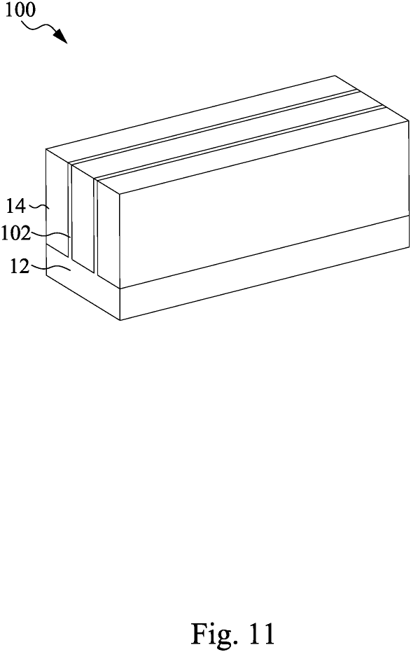

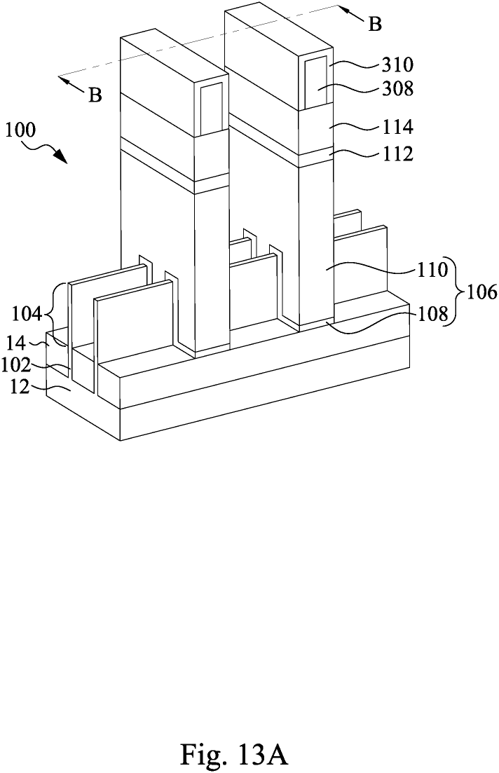

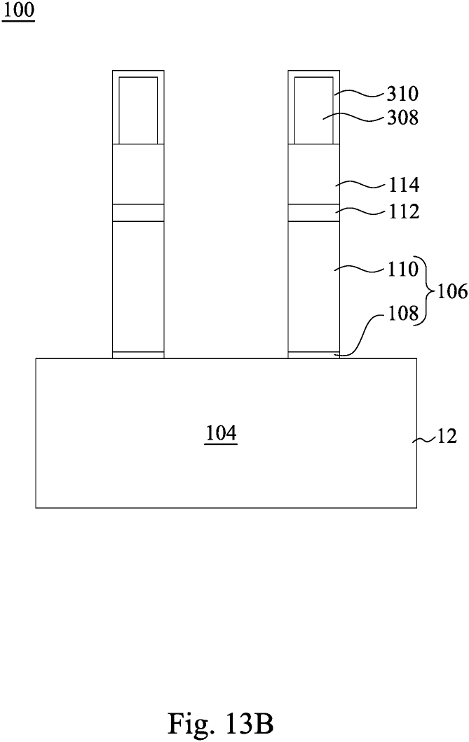

FIGS. 11, 12 and 13A illustrate perspective views of additional fabrication processes in the formation of a semiconductor device 100 using a substrate 12 in accordance with some embodiments of the present disclosure. FIGS. 13B, 14, 15 and 16 illustrate cross-sectional views of additional fabrication processes in the formation of a semiconductor device 100 using a substrate 12 in accordance with some embodiments of the present disclosure. Reference is made to FIG. 11. FIG. 11 illustrates a perspective view of an initial structure. The initial structure includes the substrate 12. The substrate 12 is similar to the workpiece 200 in terms of composition and formation, such as being patterned by a tri-layer structure including a photosensitive layer processed by a surface treatment. Isolation regions such as shallow trench isolation (STI) regions 14 may be formed to extend into the substrate 12. The portions of substrate 12 between neighboring STI regions 14 are referred to as semiconductor strips 102. As discussed previously, with reference to FIGS. 7 and 8, by using the patterned photosensitive layer 208′ protected by the protection layer 210, the overlay alignment inaccuracy and critical dimension (CD) variation can be prevented. Therefore, the pattern dimension accuracy of the semiconductor strips 102 of the substrate 12 can be improved.

STI regions 14 may include a liner oxide (not shown). The liner oxide may be formed of a thermal oxide formed through a thermal oxidation of a surface layer of the substrate 12. The liner oxide may also be a deposited silicon oxide layer formed using, for example, Atomic Layer Deposition (ALD), High-Density Plasma Chemical Vapor Deposition (HDPCVD), or Chemical Vapor Deposition (CVD). The STI regions 14 may also include a dielectric material over the liner oxide, and the dielectric material may be formed using flowable chemical vapor deposition (FCVD), spin-on coating, or the like.

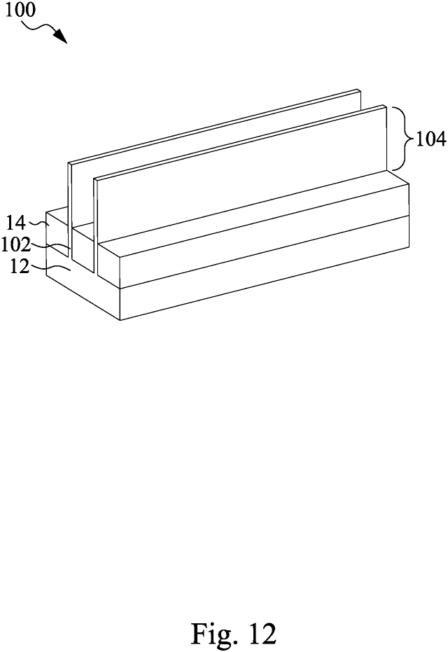

Referring to FIG. 12, the STI regions 14 are recessed, so that the top portions of semiconductor strips 102 protrude higher than the top surfaces of the neighboring STI regions 14 to form protruding fins 104. The etching may be performed using a dry etching process or a wet etching process.

The materials of fins 104 may also be replaced with materials different from that of substrate 12. For example, if the fins 104 serve for n-type transistors, protruding fins 104 may be formed of Si, SiP, SiC, SiPC, or a III-V compound semiconductor such as InP, GaAs, AlAs, InAs, InAlAs, InGaAs, or the like. On the other hand, if the fins 104 serve for p-type transistors, the protruding fins 104 may be formed of Si, SiGe, SiGeB, Ge, or a III-V compound semiconductor such as InSb, GaSb, InGaSb, or the like.

Referring to FIGS. 13A and 13B, dummy gate structures 106 are formed on the top surfaces and the sidewalls of fins 104. FIG. 13B illustrates a cross-sectional view obtained from a vertical plane containing line B-B in FIG. 13A. Formation of the dummy gate structures 106 includes depositing in sequence a blankly formed gate dielectric layer and a blankly formed dummy gate electrode layer across the fins 104, followed by patterning the blanket formed gate dielectric layer and the blankly formed dummy gate electrode layer. As a result of the patterning, the dummy gate structure 106 includes a dummy gate dielectric layer 108 and a dummy gate electrode 110 over the dummy gate dielectric layer 108. The dummy gate dielectric layers 108 can be any acceptable dielectric layer, such as silicon oxide, silicon nitride, the like, or a combination thereof, and may be formed using any acceptable process, such as thermal oxidation, a spin process, CVD, or the like. The dummy gate electrodes 110 can be any acceptable electrode layer, such as comprising polysilicon, metal, the like, or a combination thereof. The gate electrode layer can be deposited by any acceptable deposition process, such as CVD, plasma enhanced CVD (PECVD), or the like. Each of dummy gate structures 106 crosses over a single one or a plurality of fins 104. Dummy gate structures 106 may have lengthwise directions perpendicular to the lengthwise directions of the respective fins 104.

The blankly formed dummy gate electrode layer and the blankly formed gate dielectric layer may be patterned using a tri-layer structure. Bottom masks 112, top masks 114 and patterned photosensitive layers 308 protected by a protection layer 310, in which the protection layer 310 is formed by performing a surface treatment to the patterned photosensitive layers 308, are formed over the blankly formed dummy gate electrode layer in sequence. The above discussion of patterned photosensitive layers 208′ and the protection layer 210 applies to the patterned photosensitive layers 308 and the protection layer 310, respectively, unless mentioned otherwise. By using the tri-layer structure (e.g., a combination of the bottom masks 112, the top masks 114 and the patterned photosensitive layer 308 protected by the protection layer 310) as a mask, the overlay alignment inaccuracy and critical dimension (CD) variation can be prevented. Therefore, the pattern dimension accuracy of the underlying layer (e.g., the dummy gate electrodes 110 and the dummy gate dielectric layers 108) can be improved.

In an alternative embodiment, the bottom masks and the top masks are made of one or more layers of SiO₂, SiCN, SiON, Al₂O₃, SiN, or other suitable materials. In certain embodiments, the bottom masks 112 include silicon nitride, and the top masks 114 include silicon oxide.

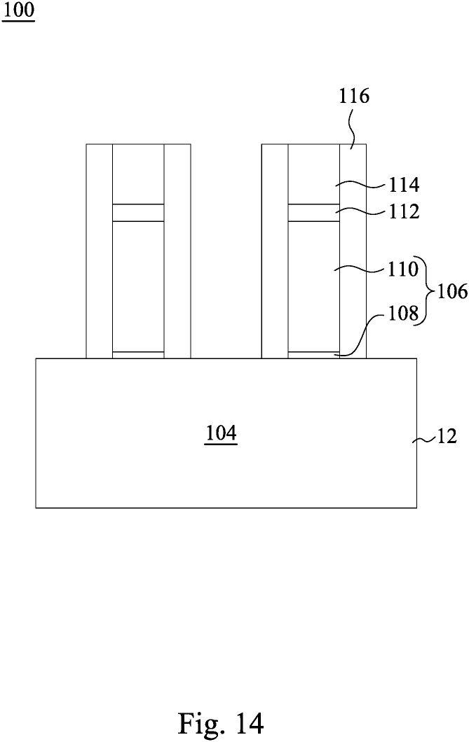

Next, as illustrated in FIG. 14, gate spacers 116 are formed on sidewalls of the dummy gate structures 106. In some embodiments of the gate spacer formation step, a spacer material layer is deposited on the substrate 12. The spacer material layer may be a conformal layer that is subsequently etched back to form gate spacers 116. The spacer material layer is made of a low-k dielectric material. The low-k dielectric material has a dielectric constant (k value) of lower than about 3.5. Suitable materials for the low-k dielectric material may include, but are not limited to, doped silicon dioxide, fluorinated silica glass (FSG), carbon-doped silicon dioxide, porous silicon dioxide, porous carbon-doped silicon dioxide, SiLK™ (an organic polymeric dielectric distributed by Dow Chemical of Michigan), Black Diamond (a product of Applied Materials of Santa Clara, Calif.), Xerogel, Aerogel, amorphous fluorinated carbon, Parylene, bis-benxocyclocutenes (BCB), polyimide, polynoroboneses, benzocyclocutene, PTFE, porous SiLK, hydrogen silsesquioxane (HSQ), methylsilsesquioxane (MSQ), and/or combinations thereof. By way of example and not limitation, the spacer material layer may be formed using processes such as, CVD process, a subatmospheric CVD (SACVD) process, a flowable CVD process, an ALD process, a physical vapor deposition (PVD) process, or other suitable process. An anisotropic etching process is then performed on the deposited spacer material layer to expose portions of the fins 104 not covered by the dummy gate structures 106 (e.g., in source/drain regions of the fins 104). Portions of the spacer material layer directly above the dummy gate structures 106 may be completely removed by this anisotropic etching process. Portions of the spacer material layer on sidewalls of the dummy gate structures 106 may remain, forming gate spacers, which are denoted as the gate spacers 116, for the sake of simplicity. In some embodiments, the gate spacers 116 may be used to offset subsequently formed doped regions, such as source/drain regions. The gate spacers 116 may further be used for designing or modifying the source/drain region profile.

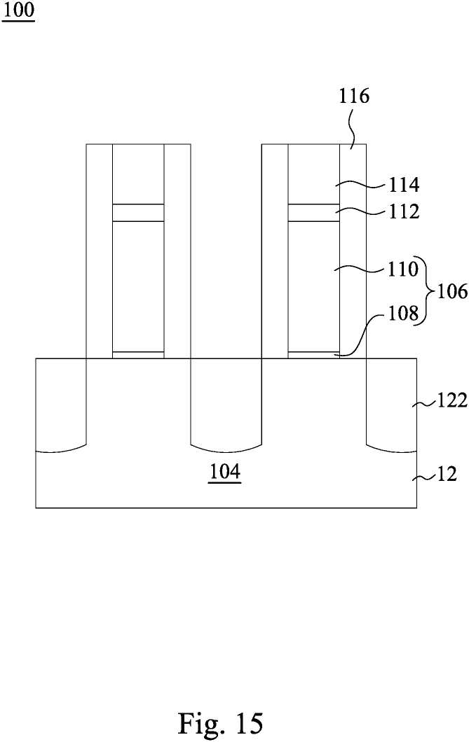

In FIG. 15, after formation of the gate spacers 116 is completed, source/drain epitaxial structures 122 are formed on source/drain regions of the protruding fins 104 that are not covered by the dummy gate structures 106 and the gate spacers 116. In some embodiments, formation of the source/drain epitaxial structures 122 includes recessing source/drain regions of the fin 104, followed by epitaxially growing semiconductor materials in the recessed source/drain regions of the fin 104. The source/drain epitaxial structures 122 are on opposite sides of the dummy gate structure 106.

The source/drain regions of the fins 104 can be recessed using suitable selective etching processing that attacks the fins 104, but hardly attacks the gate spacers 116 and the top masks 114 of the dummy gate structures 106. For example, recessing the fins 104 may be performed by a dry chemical etch with a plasma source and an etchant gas. The plasma source may be inductively coupled plasma (ICR) etch, transformer coupled plasma (TCP) etch, electron cyclotron resonance (ECR) etch, reactive ion etch (RIE), or the like and the etchant gas may be fluorine, chlorine, bromine, combinations thereof, or the like, which etches the protruding fins 104 at a faster etch rate than it etches the gate spacers 116 and the top masks 114 of the dummy gate structures 106. In some other embodiments, recessing the protruding fins 104 may be performed by a wet chemical etch, such as ammonium peroxide mixture (APM), NH₄OH, tetramethylammonium hydroxide (TMAH), combinations thereof, or the like, which etches the fins 104 at a faster etch rate than it etches the gate spacers 116 and the top masks 114 of the dummy gate structures 106. In some other embodiments, recessing the protruding fins 104 may be performed by a combination of a dry chemical etch and a wet chemical etch.

Once recesses are created in the source/drain regions of the fin 104, source/drain epitaxial structures 122 are formed in the source/drain recesses in the fin 104 by using one or more epitaxy or epitaxial (epi) processes that provides one or more epitaxial materials on the protruding fins 104. During the epitaxial growth process, the gate spacers 116 limit the one or more epitaxial materials to source/drain regions in the fin 104. In some embodiments, the lattice constants of the source/drain epitaxial structures 122 are different from the lattice constant of the fins 104, so that the channel region in the fin 104 and between the source/drain epitaxial structures 122 can be strained or stressed by the source/drain epitaxial structures 122 to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the fins 104.

In some embodiments, the source/drain epitaxial structures 122 may include Ge, Si, GaAs, AlGaAs, SiGe, GaAsP, SiP, or other suitable material. The source/drain epitaxial structures 122 may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 122 are not in-situ doped, an implantation process (i.e., a junction implant process) is performed to dope the source/drain epitaxial structures 122. In some exemplary embodiments, the source/drain epitaxial structures 122 in an n-type transistor include SiP, while those in a p-type include GeSnB and/or SiGeSnB. In embodiments with different device types, a mask, such as a photoresist, may be formed over n-type device regions, while exposing p-type device regions, and p-type epitaxial structures may be formed on the exposed fins 104 in the p-type device regions. The mask may then be removed. Subsequently, a mask, such as a photoresist, may be formed over the p-type device region while exposing the n-type device regions, and n-type epitaxial structures may be formed on the exposed fins 104 in the n-type device region. The mask may then be removed.

Once the source/drain epitaxial structures 122 are formed, an annealing process can be performed to activate the p-type dopants or n-type dopants in the source/drain epitaxial structures 122. The annealing process may be, for example, a rapid thermal anneal (RTA), a laser anneal, a millisecond thermal annealing (MSA) process or the like.

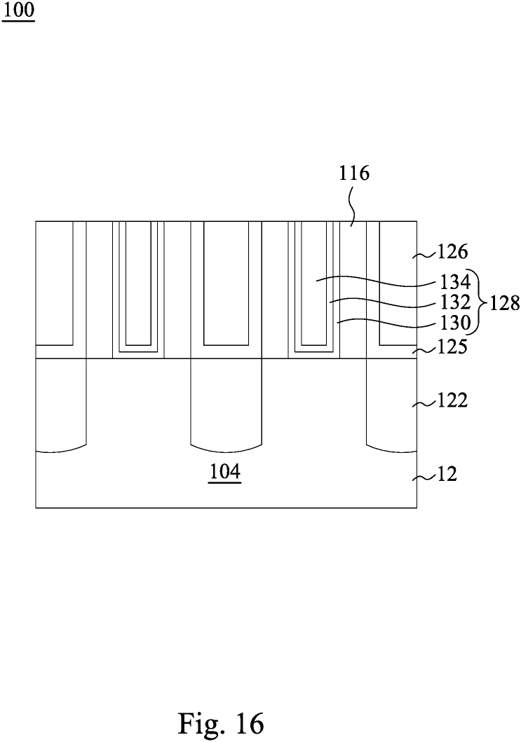

Next, in FIG. 16, a contact etch stop layer (CESL) 125 and an interlayer dielectric (ILD) layer 126 are formed on the substrate 12 in sequence. In some examples, the CESL 125 includes a silicon nitride layer, silicon oxide layer, a silicon oxynitride layer, and/or other suitable materials having a different etch selectivity than the ILD layer 126. The CESL 125 may be formed by plasma-enhanced chemical vapor deposition (PECVD) process and/or other suitable deposition or oxidation processes. In some embodiments, the ILD layer 126 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL 125. The ILD layer 126 may be deposited by a PECVD process or other suitable deposition technique. In some embodiments, after formation of the ILD layer 126, the wafer may be subject to a high thermal budget process to anneal the ILD layer 126.

In some examples, after forming the ILD layer 126, a planarization process may be performed to remove excessive materials of the ILD layer 126 and the CESL 125. For example, a planarization process includes a chemical mechanical planarization (CMP) process which removes portions of the ILD layer 126 and the CESL 125 overlying the dummy gate structures 106. In some embodiments, the CMP process also removes bottom masks 112 and top masks 114 (as shown in FIG. 15) and exposes the dummy gate electrodes 110.

An etching process is performed to remove the dummy gate electrode 110 and the dummy gate dielectric layer 108, resulting in gate trenches between corresponding gate spacers 116. The dummy gate structures 106 are removed using a selective etching process (e.g., selective dry etching, selective wet etching, or a combination thereof) that etches materials in the dummy gate structures 106 at a faster etch rate than it etches other materials (e.g., gate spacers 116 and/or the ILD layer 126).

Thereafter, replacement gate structures 128 are respectively formed in the gate trenches. The gate structures 128 may be the final gates of FinFETs. In FinFETs, the fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. The final gate structures each may be a high-k/metal gate (HKMG) stack, however other compositions are possible. In some embodiments, each of the gate structures 128 forms the gate associated with the three-sides of the channel region provided by the fin 104. Stated another way, each of the gate structures 128 wraps around the fin 104 on three sides. In various embodiments, the high-k/metal gate structure 128 includes a gate dielectric layer 130 lining the gate trench, a work function metal layer 132 formed over the gate dielectric layer 130, and a fill metal 134 formed over the work function metal layer 132 and filling a remainder of gate trenches. The gate dielectric layer 130 includes an interfacial layer (e.g., silicon oxide layer) and a high-k gate dielectric layer over the interfacial layer. High-k gate dielectrics, as used and described herein, include dielectric materials having a high dielectric constant, for example, greater than that of thermal silicon oxide (~3.9). The work function metal layer 132 and/or the fill metal 134 used within high-k/metal gate structures 128 may include a metal, metal alloy, or metal silicide. Formation of the high-k/metal gate structures 128 may include multiple deposition processes to form various gate materials, one or more liner layers, and one or more CMP processes to remove excessive gate materials.

In some embodiments, the interfacial layer of the gate dielectric layer 130 may include a dielectric material such as silicon oxide (SiO₂), HfSiO, or silicon oxynitride (SiON). The interfacial layer may be formed by chemical oxidation, thermal oxidation, atomic layer deposition (ALD), chemical vapor deposition (CVD), and/or other suitable method. The high-k dielectric layer of the gate dielectric layer 130 may include hafnium oxide (HfO₂). Alternatively, the gate dielectric layer 130 may include other high-k dielectrics, such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof.

The work function metal layer 132 may include work function metals to provide a suitable work function for the high-k/metal gate structures 128. For an n-type FinFET, the work function metal layer 132 may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type FinFET, the work function metal layer 132 may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials.

In some embodiments, the fill metal 134 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAIN, or other suitable materials.

In some embodiments, the semiconductor device 100 includes other layers or features not specifically illustrated. In some embodiments, back end of line (BEOL) processes are performed on the semiconductor device 100. In some embodiments, the semiconductor device 100 is formed by a non-replacement metal gate process or a gate-first process.

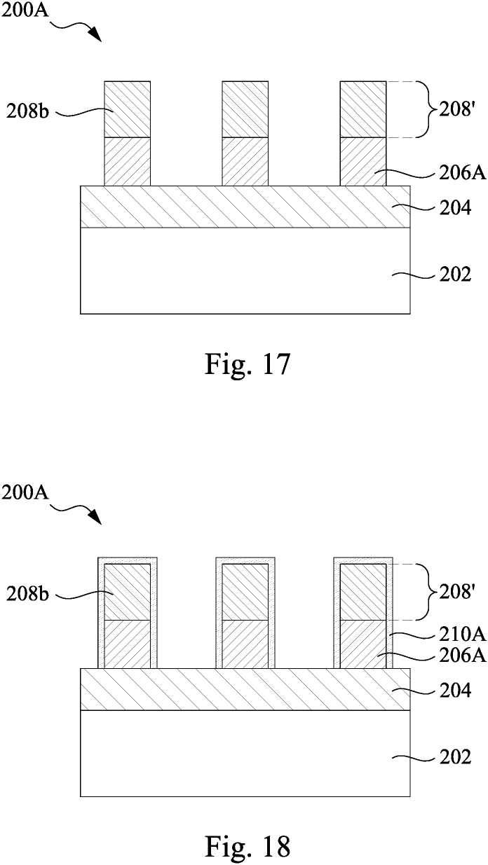

FIGS. 17-21 show processes for manufacturing a semiconductor device according to other embodiments of the present disclosure. It is understood that additional operations can be provided before, during, and after processes shown by FIGS. 17-21, and some of the operations described below can be replaced or eliminated, for additional embodiments of the method. The order of the operations/processes may be interchangeable. Materials, configurations, dimensions, processes, and/or operations the same as or similar to those explained with respect to FIGS. 3-10 may be employed in the following embodiments, and the detailed explanation thereof may be omitted.

After the structure shown in FIG. 5 is formed, the middle layer 206 is patterned (illustrated as a patterned middle layer 206A) as shown in FIG. 17. Unlike the structure shown in FIG. 5, in which the middle layer 206 is un-patterned prior to performing the surface treatment to form the protection layer 210, the middle layer 206 is patterned prior to forming the protection layer 210A (see FIG. 17) on the substrate 202. Reference is made to FIG. 18. A surface treatment is performed to the patterned photosensitive layer 208′ and the patterned middle layer 206A. Accordingly, the protection layer 210A is formed to surround the patterned middle layer 206A and the patterned photosensitive layer 208′.

As described in greater detail below, the protection layer 210A is configured to protect the patterned photosensitive layer 208′ and the patterned middle layer 206A.

To protect the patterned photosensitive layer 208′ and the patterned middle layer 206A, the protection layer 210A includes a cross-linkable composition. The cross-linkable composition has a reactive functional group configured to cross-link or interact with an exposed surface of the patterned photosensitive layer 208′ and an exposed surface of the patterned middle layer 206A while not reacting with or not cross-linking an exposed surface of the bottom layer 204. In greater detail, the protection layer 210A reacts with a top surface and sidewalls of the patterned photosensitive layer 208′ and with sidewalls of the patterned middle layer 206A in a cross-link reaction. For example, the cross-linkable composition of the protection layer 210A may include one or more of repeating units 1-8 of FIG. 22.

In some embodiments, the surface treatment to form the protection layer 210A is carried out by dispensing, vapor deposition, soaking the workpiece 200A into a bath, or other suitable methods.

In some embodiments, after the top surface and the sidewalls of the patterned photosensitive layer 208′ and the sidewalls of the patterned middle layer 206A are protected by the protection layer 210A, an unreacted portion of the protection layer 210A is removed. In some embodiments, the unreacted portion is removed by performing a rinsing process using water (e.g., de-ionized water) or organic solvent as a rinsing agent. In some embodiments, a baking process may be further performed before or after removing the unreacted portion of the protection layer 210A. The baking process is configured to help the protection layer 210A to be fixed onto the top surface and the sidewalls of the patterned photosensitive layer 208′ and onto the sidewalls of the middle layer.

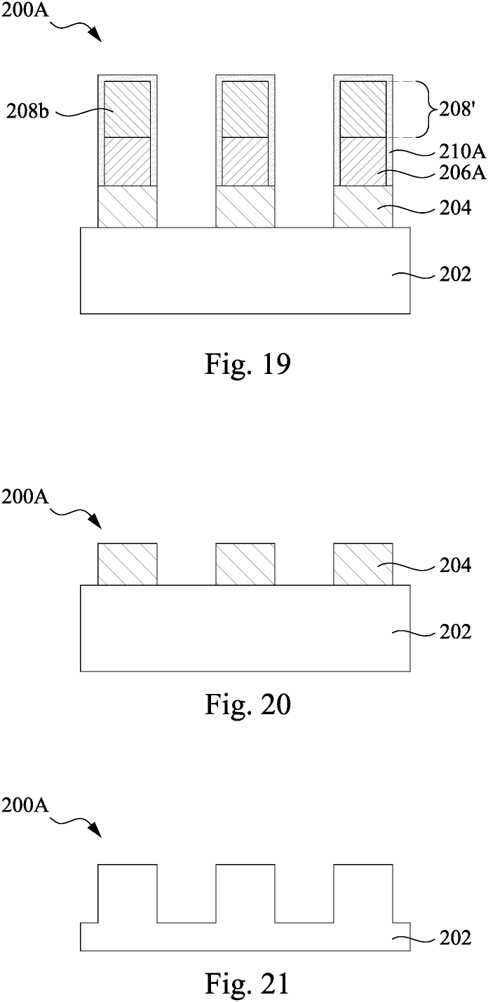

Referring to FIG. 19, portions of the bottom layer 204 are selectively removed in an etching process using the patterned photosensitive layer 208′ and the patterned middle layer 206A, which are both protected by the protective layer 210A, together as an etch mask.. The process of etching the bottom layer 204 can be chosen such that the bottom layer 204 has an etch rate higher than an etch rate of the protection layer 210A. In some embodiments, although the patterned photosensitive layer 208′ and the patterned middle layer 206A may have a low etch resistance to the etching process of etching the bottom layer 204, the protection layer 210A has a higher etch resistance to the etching process of etching the bottom layer 204 than that of the patterned photosensitive layer 208′ and the patterned middle layer 206A. Therefore, the etching conditions (e.g., etchant chemicals, temperature, pressure, bias of dry etching, pH value of wet etching, and so on) for etching the bottom layer 204 can be selected to form an improved sidewall profile for the bottom layer 204, with more relaxed concern about damages to the photosensitive layer 208 and the middle layer 206. In this way, the resultant bottom layer 204 can have a substantially vertical sidewall profile without significantly damaging the vertical sidewall profile of the photosensitive layer 208 and the middle layer 206. As a result, the overlay alignment inaccuracy and critical dimension (CD) variation can be prevented. The bottom layer 204 is patterned using any suitable method similar to the processes as described for the embodiments shown in FIG. 8.

The patterned photosensitive layer 208′ and the protection layer 210A are subsequently removed from the workpiece 200A by an ashing operation or any suitable method. Afterwards, the patterned middle layer 206A is removed by any suitable method.

Referring to FIG. 20, the substrate 202 is processed using the patterned bottom layer 204 as a mask. Any suitable method may be performed to process the substrate 202 including a deposition process, an implantation process, an epitaxial growth process, and/or any other fabrication process. In an exemplary embodiment, the substrate 202 is etched using the patterned bottom layer 204 as an etch mask. In some embodiments, the substrate 202 is etched using any suitable method including a dry etching process, a wet etching process, other suitable etching process, an RIE process, or combinations thereof. However, it is understood that the concepts of the present disclosure apply to any fabrication process performed on the substrate 202. In various examples, the processed substrate 202 is used to fabricate a gate stack, to fabricate an interconnect structure, to form non-planar devices by etching to expose a fin or by epitaxially growing fin material, and/or other suitable applications. The patterned bottom layer 204 is subsequently removed using any suitable method after the substrate 202 is processed.

Referring to FIG. 21, the workpiece 200A may then be provided for additional fabrication processes. For example, the workpiece 200A may be used to fabricate an integrated circuit chip, a system-on-a-chip (SOC), and/or a portion thereof, and thus the subsequent fabrication processes may form various passive and active microelectronic devices such as resistors, capacitors, inductors, diodes, metal-oxide semiconductor field effect transistors (MOSFET), complementary metal-oxide semiconductor (CMOS) transistors, bipolar junction transistors (BJT), laterally diffused MOS (LDMOS) transistors, high power MOS transistors, other types of transistors, and/or other circuit elements.

Based on the above discussions, it can be seen that the present disclosure offers advantages over conventional methods. It is understood, however, that other embodiments may offer additional advantages, and not all advantages are necessarily disclosed herein, and that no particular advantage is required for all embodiments. One advantage is that by performing a surface treatment to the photosensitive layer prior to etching the middle layer or performing a surface treatment to the photosensitive layer and the middle layer prior to etching the bottom layer, overlay alignment inaccuracy and critical dimension (CD) variation can be prevented, thus improving the quality of the middle layer and the bottom layer during the lithography patterning process.

In some embodiments, a method includes forming a tri-layer structure over a substrate, in which the tri-layer structure includes a bottom layer, a middle layer over the bottom layer and a photosensitive layer, patterning the photosensitive layer, performing a surface treatment on the patterned photosensitive layer to form a protection layer at least on a sidewall of the patterned photosensitive layer, patterning the middle layer after performing the surface treatment, patterning the bottom layer, and etching the substrate. In some embodiments, the protection layer comprises a cross-linkable composition. In some embodiments, the cross-linkable composition of the protection layer cross-links the sidewall of the patterned photosensitive layer but does not cross-link the middle layer. In some embodiments, the cross-linkable composition comprises a repeating unit comprising a chemical formula of one of the following:

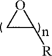

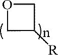

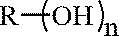

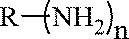

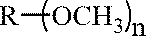

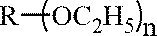

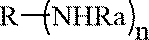

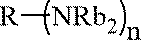

in which R is alkyl group, cycloalkyl group, hydroxylalkyl group, alkoxy group, alkoxyl alkyl group, acetyl group, acetyl alkyl group, aromatic group, halogen alkyl, or halogen alkyl containing aromatic derivatives, Ra and Rb are each independently C1-C6 alkyl group, cycloalkyl group, hydroxylalkyl group, alkoxy group, alkoxyl alkyl group, acetyl group, or acetyl alkyl group, and n is in a range from 1 to 200. In some embodiments, the protection layer further comprises an organic solvent having a partition ratio (log P) value of lower than 4. In some embodiments, performing the surface treatment to form the protection layer includes performing a baking process to the protection layer and performing a rinsing process to remove an unreacted portion of the protection layer. In some embodiments, the patterned photosensitive layer is removed after patterning the bottom layer.

In some embodiments, a method includes forming a tri-layer structure over a substrate, in which the tri-layer structure includes a bottom layer, a middle layer over the bottom layer and a photosensitive layer, patterning the photosensitive layer, patterning the middle layer, after patterning the middle layer, performing a surface treatment on the photosensitive layer to form a protection layer cross-linking a sidewall of the patterned middle layer, a sidewall of the patterned photosensitive layer and a top surface of the patterned photosensitive layer, patterning the bottom layer, and etching the substrate. In some embodiments, the protection layer is removed after patterning the bottom layer. In some embodiments, patterning the bottom layer is performed using the patterned middle layer and the patterned photosensitive layer as an etch mask, and the patterned middle layer and the patterned photosensitive layer are both protected by the protection layer during patterning the bottom layer. In some embodiments, the protection layer does not cross-link the bottom layer during performing the surface treatment. In some embodiments, patterning the middle layer is performed using a wet etching employing an etchant solution with a pH value of greater than 8 or lower than 5. In some embodiments, patterning the middle layer is performed by a dry etching using an etchant gas comprising oxygen, nitrogen, hydrogen, a fluorine-containing etchant gas, or combinations thereof. In some embodiments, patterning the bottom layer is performed by a wet etching using an etchant solution with a pH value of greater than 8 or lower than 5. In some embodiments, patterning the bottom layer is performed by a dry etching using an etchant gas comprising oxygen, nitrogen, hydrogen and/or a fluorine-containing etchant gas.

In some embodiments, a method includes forming a tri-layer structure over a substrate, in which the tri-layer structure includes a bottom layer, a middle layer over the bottom layer and a photosensitive layer, patterning the photosensitive layer, performing a surface treatment to form a protection layer cross-linking the patterned photosensitive layer but not cross-linking the middle layer, patterning the middle layer, patterning the bottom layer and etching the substrate. In some embodiments, the photosensitive layer includes photoresist, spin-on carbon (SOC) or spin-on glass (SOG). In some embodiments, the method further includes after patterning the bottom layer, ashing the patterned photosensitive layer and the protection layer. In some embodiments, the surface treatment is performed using dispensing, vapor deposition or soaking in a bath. In some embodiments, the method of claim further includes performing a rinsing process to remove an unreacted portion of the protection layer using water or organic solvent as a rinsing agent.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a tri-layer structure over a substrate, wherein the tri-layer structure comprises:
a bottom layer;
a middle layer over the bottom layer; and
a photosensitive layer;
patterning the photosensitive layer;
performing a surface treatment on the patterned photosensitive layer to form a protection layer at least on a sidewall of the patterned photosensitive layer;
patterning the middle layer after performing the surface treatment;
patterning the bottom layer; and
etching the substrate.

2. The method of claim 1, wherein the protection layer comprises a cross-linkable composition.

3. The method of claim 2, wherein the cross-linkable composition of the protection layer cross-links the sidewall of the patterned photosensitive layer but does not cross-link the middle layer.

4. The method of claim 2, wherein the cross-linkable composition comprises a repeating unit comprising a chemical formula of one of the following: 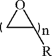 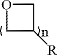 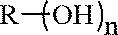 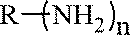 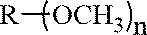 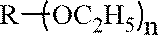 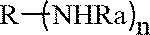 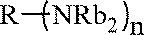
, wherein R is alkyl group, cycloalkyl group, hydroxylalkyl group, alkoxy group, alkoxyl alkyl group, acetyl group, acetyl alkyl group, aromatic group, halogen alkyl, or halogen alkyl containing aromatic derivatives, Ra and Rb are each independently C1-C6 alkyl group, cycloalkyl group, hydroxylalkyl group, alkoxy group, alkoxyl alkyl group, acetyl group, or acetyl alkyl group, and n is in a range from 1 to 200.

5. The method of claim 2, wherein the protection layer further comprises an organic solvent having a partition ratio (log P) value of lower than 4.

6. The method of claim 1, wherein performing the surface treatment to form the protection layer comprises:
performing a baking process to the protection layer; and
performing a rinsing process to remove an unreacted portion of the protection layer.

7. The method of claim 1, wherein the patterned photosensitive layer is removed after patterning the bottom layer.

8. A method, comprising:
forming a tri-layer structure over a substrate, wherein the tri-layer structure comprises:
a bottom layer;
a middle layer over the bottom layer; and
a photosensitive layer;
patterning the photosensitive layer;
patterning the middle layer;
after patterning the middle layer, performing a surface treatment on the photosensitive layer to form a protection layer cross-linking a sidewall of the patterned middle layer, a sidewall of the patterned photosensitive layer and a top surface of the patterned photosensitive layer;
patterning the bottom layer; and
etching the substrate.

9. The method of claim 8, wherein the protection layer is removed after patterning the bottom layer.

10. The method of claim 8, wherein patterning the bottom layer is performed using the patterned middle layer and the patterned photosensitive layer as an etch mask, and the patterned middle layer and the patterned photosensitive layer are both protected by the protection layer during patterning the bottom layer.

11. The method of claim 8, wherein the protection layer does not cross-link the bottom layer during performing the surface treatment.

12. The method of claim 8, wherein patterning the middle layer is performed using a wet etching employing an etchant solution with a pH value of greater than 8 or lower than 5.

13. The method of claim 8, wherein patterning the middle layer is performed by a dry etching using an etchant gas comprising oxygen, nitrogen, hydrogen, a fluorine-containing etchant gas, or combinations thereof.

14. The method of claim 8, wherein patterning the bottom layer is performed by a wet etching using an etchant solution with a pH value of greater than 8 or lower than 5.

15. The method of claim 8, wherein patterning the bottom layer is performed by a dry etching using an etchant gas comprising oxygen, nitrogen, hydrogen and/or a fluorine-containing etchant gas.

16. A method, comprising:
forming a tri-layer structure over a substrate, wherein the tri-layer structure comprises:
a bottom layer;
a middle layer over the bottom layer; and
a photosensitive layer;
patterning the photosensitive layer;
performing a surface treatment to form a protection layer cross-linking the patterned photosensitive layer but not cross-linking the middle layer;
patterning the middle layer;
patterning the bottom layer; and
etching the substrate.

17. The method of claim 16, wherein the photosensitive layer comprises photoresist, spin-on carbon (SOC) or spin-on glass (SOG).

18. The method of claim 16, further comprising:
after patterning the bottom layer, ashing the patterned photosensitive layer and the protection layer.

19. The method of claim 16, wherein the surface treatment is performed using dispensing, vapor deposition or soaking in a bath.

20. The method of claim 19, further comprising:
performing a rinsing process to remove an unreacted portion of the protection layer using water or organic solvent as a rinsing agent.
